(19) United States
(12) Patent Application Publication
(10) Pub. No.: US 2002/0079530 A1
(43) Pub. Date: Jun. 27, 2002

(54) Electronic circuit with electrical hole isolator

(76) Inventors: Xiaoju Wu, Irving, TX (US); Pinhai Hao, Dallas, TX (US); Imran Khan, Richardson, TX (US); Jozef C. Mitros, Richardson, TX (US); James R. Todd, Plano, TX (US); Robert Pan, Plano, TX (US)

Correspondence Address: TEXAS INSTRUMENTS INCORPORATED, P O BOX 655474, M/S 3999, DALLAS, TX, 75265

(21) Appl. No.: 10/017,990

(22) Filed: Dec. 14, 2001

Related U.S. Application Data
(60) Provisional application No. 60/257,922, filed on Dec. 21, 2000.

(51) Int. Cl. H01L 27/108

(52) U.S. Cl. 257/302

(57) ABSTRACT

An electronic circuit (20), comprising a semiconductor substrate (22) and a first layer (30) in a fixed physical relation to the semiconductor substrate. The electronic circuit further comprises a well (32a) formed in the first layer, wherein the well comprises a first conductivity type and has a side dimension and a bottom dimension. The electronic circuit further comprises a first enclosure (34, 26) surrounding the side dimension and the bottom dimension of the well, wherein the first enclosure comprises a second conductivity type complementary of the first conductivity type and has a side dimension and a bottom dimension. The electronic circuit further comprises a second enclosure (32b, 24) surrounding the side dimension and the bottom dimension of the first enclosure, wherein the second enclosure comprises the first conductivity type.

### CROSS-REFERENCES TO RELATED APPLICATIONS

Not Applicable.

### STATEMENT REGARDING FEDERALLY SPONSORED RESEARCH OR DEVELOPMENT

Not Applicable.

### BACKGROUND OF THE INVENTION

The present embodiments relate to semiconductor electronic circuits and are more particularly directed to an electronic circuit with an electrical hole isolator.

Various semiconductor devices are constructed in the art using a semiconductor substrate. Often numerous devices share such a substrate and, therefore, the electrical effects that one device may have on the substrate may be imposed on another device sharing the same substrate. These effects are sometimes reduced by adjusting the substrate potential to a certain value, such as ground or by designing circuits to reduce the amount of emissions that may affect the substrate. However, such approaches may not be always feasible, yet without such an approach the results may complicate overall device design and also may affect circuit operation predictability.

One type of circuit that lends itself to the issues raised above is a vertical PNP transistor, an example of which is shown in a cross-sectional view in FIG. 1 generally as transistor 10. Transistor 10 is formed using a substrate 12, which in the example of FIG. 1 is a p-type semiconductor material and which therefore is also labeled with a P designation. An n-type well 14 is formed within substrate 12, such as by masking the upper surface of substrate and implanting an appropriate dopant such as arsenic or phosphorus. Two p-type diffusion regions 16 and 18 are formed at the surface of substrate 12, where p-type region 16 is formed within n-type well 14 while p-type region 18 is formed outside of n-type well 14, that is, in direct electrical contact with substrate 12. P-type regions 16 and 18 are also formed within substrate 12 by masking the upper surface of substrate and implanting an appropriate dopant in the locations correspondingly illustrated as regions 16 and 18 in FIG. 1, where a common p-type dopant is boron. The doping concentration of regions 16 and 18 is higher than that of substrate 12 and, hence, each region is also labeled with a P+ designation. An n-type diffusion region 20 is formed at the surface of substrate 12 and also within n-type well 14. Lastly, and although not shown to simplify FIG. 1, one skilled in the art will recognize that insulating regions such as field oxides are typically formed along the upper surface of substrate 12 and separating each of regions 16, 18, and 20 from one another.

Given the various locations and conductivity types of the regions and well of transistor 10 as well as the relative location of those regions with respect to substrate 12, one skilled in the art will readily appreciate that a PNP conductivity path may be established from p-type region 18 and substrate 12, to n-type well 14 (and n-type region 20), to p-type region 16. Indeed, this conductivity path establishes a PNP transistor configuration and, for this reason, p-type region 18 provides the device collector and is indicated schematically as C₁, n-type well 14 and n-type region 20 provide the device base and n-type region 20 is indicated schematically as B₁, and p-type region 16 provides the device emitter and is indicated schematically as E₁. Lastly, the current flow in the vertical dimension is dominant for transistor 10 and, hence, transistor 10 is often referred to as a vertical PNP transistor.

Having illustrated the various nodes of transistor 10, attention is directed to the potentially undesirable effects of stray holes in the operation of transistor 10. Specifically, as known in the transistor art, a collector is so named because during operation it collects electrical holes in response to the collector-to-base voltage and further due to the depletion region that occurs along the P/N interface between collector C₁ and base B₁. However, for the prior art device in FIG. 1, note that some holes may not be collected by collector C₁ and instead those holes may stray into substrate 12. Further, although not illustrated, typically substrate 12 may support numerous other devices. As a result, the stray holes in substrate 12 may reach any one of these other devices, thereby affecting the operation of the other device in a possibly undesirable manner.

In view of the above, there arises a need to address the drawbacks of stray holes that arise from the failure to collect those holes in a satisfactory manner, and these drawbacks are addressed by the preferred embodiments as detailed below.

### BRIEF SUMMARY OF THE INVENTION

In the preferred embodiment, there is an electronic circuit comprising a semiconductor substrate and a first layer in a fixed physical relation to the semiconductor substrate. The electronic circuit further comprises a well formed in the first layer, wherein the well comprises a first conductivity type and has a side dimension and a bottom dimension. The electronic circuit further comprises a first enclosure surrounding the side dimension and the bottom dimension of the well, wherein the first enclosure comprises a second conductivity type complementary of the first conductivity type and has a side dimension and a bottom dimension. The electronic circuit further comprises a second enclosure surrounding the side dimension and the bottom dimension of the first enclosure, wherein the second enclosure comprises the first conductivity type. Various other attributes and methods are also disclosed and claimed.

### BRIEF DESCRIPTION OF THE SEVERAL VIEWS OF THE DRAWING

FIG. 1 illustrates a cross-sectional view of a prior art vertical PNP transistor.

FIG. 2a illustrates a cross-sectional view of a preferred embodiment PNP transistor after some initial fabrication steps.

FIG. 2b illustrates a cross-sectional view of transistor 20 after additional fabrication steps following those illustrated in FIG. 2a.

FIG. 2c illustrates a cross-sectional view of transistor 20 after additional fabrication steps following those illustrated in FIG. 2b.

FIG. 2d illustrates a top view of transistor 20 from FIG. 2c.

FIG. 3 illustrates a cross-sectional view of a preferred embodiment electrical hole isolator circuit.

### DETAILED DESCRIPTION OF THE INVENTION

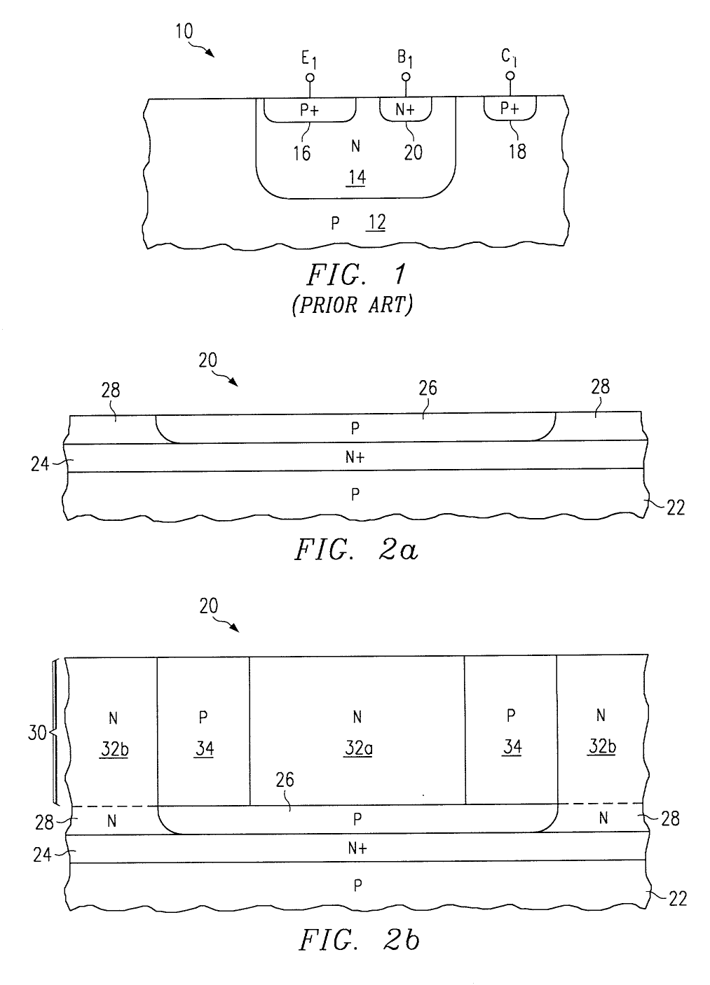

FIG. 1 was described in the earlier Background Of The Invention section of this document, and the reader is assumed to be familiar with the details described relative to FIG. 1.

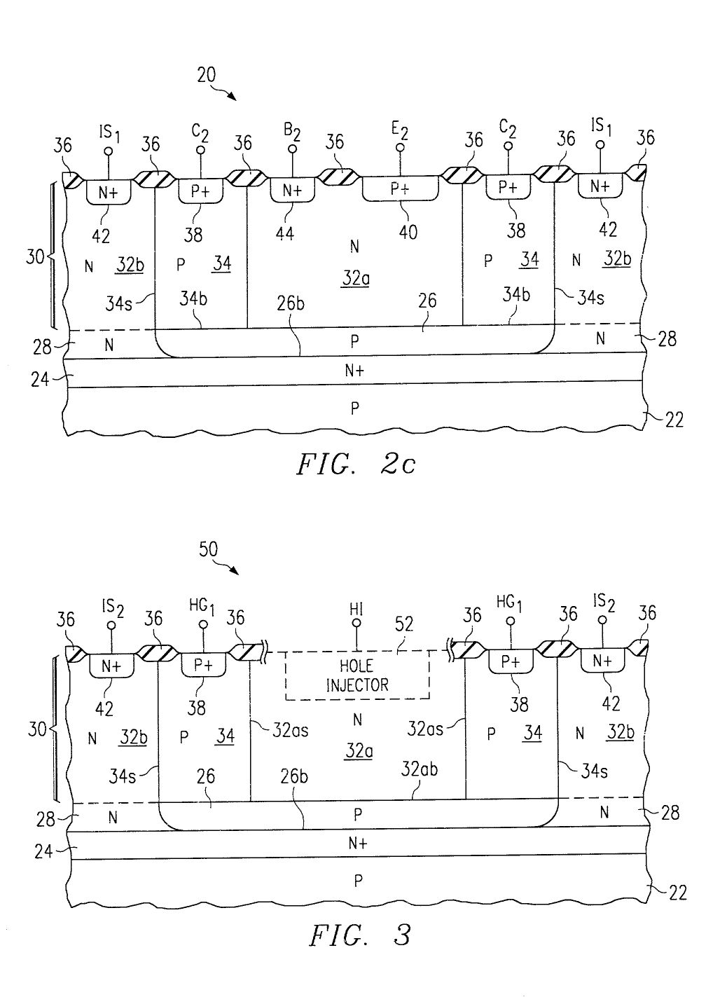

FIG. 2a illustrates a cross-sectional view of a preferred embodiment PNP transistor 20 after some initial fabrication steps. In FIG. 2a, transistor 20 is formed from a p-type substrate 20 which, due to its conductivity type, is labeled generally with a P designation. An n-type buried layer 24 is formed overlying p-type substrate 22, and due to its conductivity type layer 24 is labeled generally with an N designation. N-type buried layer 24 is preferably formed by masking the upper surface of substrate 22 and then implanting an appropriate n-type dopant, such as arsenic or antimony, into that upper surface. By way of a preferred example, the antimony is implanted at a dosage of 5e¹⁵/cm² and at an energy of 60 keV. Note that the doping concentration is relatively high and, thus, n-type buried layer 24 is labeled with an N+ designation. In addition, a subsequent diffusion step is performed after the implant, such as by way of a heating (e.g., annealing) process. Finally, note that layer 24 is referred to as a “buried layer” instead of a well because an additional semiconductor layer is formed on top of it as shown in later figures. However, the phrase “buried layer” should not unnecessarily limit the range of the inventive scope and, indeed, a layer of the type as layer 24 may be referred to in the art using other terminology. To the extent that other terms are consistent with the formation and function of buried layer 24 as described in this document, then they too are intended within the present inventive scope.

Continuing with FIG. 2a, a p-type buried layer 26 is formed within n-type buried layer 24. P-type buried layer 26 is preferably formed by masking the upper surface of n-type buried layer 24 (and substrate 22, where exposed) and then implanting an appropriate p-type dopant, such as boron, into areas exposed by the mask. By way of a preferred example, the boron may be implanted at a dosage of 8e¹³/cm² and at an energy of 60 keV, and as a result of these dopants p-type buried layer 26 is labeled with a P designation. Note that due to the depth of the dopants forming n-type buried layer 24 as well as the formation of p-type buried layer 26, regions 28 may exist to the outside of p-type buried layer 26 and above n-type buried layer 24. The doping level in regions 28 as of the point in FIG. 2a may vary due in part to the original p-type nature of substrate 22 and further due to the n-type dopants used to form n-type buried layer 24. Regardless, the result at this point in the fabrication of transistor 20 is later changed in that regions 28 are further doped in a subsequent step as detailed below.

FIG. 2b illustrates a cross-sectional view of transistor 20 after additional fabrication steps following those illustrated in FIG. 2a. An epitaxial layer 30 is formed (e.g., deposited) over substrate 22, which therefore overlies p-type buried layer 26 and regions 28. In the preferred embodiment, epitaxial layer 30 is formed with a light p-type doping, such as using in-situ doping. Further, in the preferred embodiment, epitaxial layer 30 is on the order of 3.5 microns thick or less depending on the specific applications.

After layer 30 is formed, its upper surface is appropriately masked an n-type wells 32a and 32b are formed by implanting n-type dopants (e.g., phosphorus) through the mask. While the preferred embodiment therefore forms n-type wells 32a and 32b at the same time, they are labeled with different identifiers for the sake of reference and due to various differences between the two. More particularly, because of the location and dopant concentration of p-type buried layer 26, the n-type dopants used to form n-type well 32a do not sufficiently counterdope in the area of p-type buried layer 26; in contrast, those same n-type dopants form n-type well 32b, but at the bottom of that well is region 28 which recall from above may after the formation of the structure in FIG. 2a have varying dopants, but will include some n-type dopants from the formation of n-type buried layer 24 and will include far less p-type dopants as compared to p-type buried layer 26. In any event, therefore, the n-type dopants used to form n-type well 32b also penetrate region 28 such that n-type well 32b actually extends into the area of region 28; thus, region 28 is rendered n-type due to a combination of diffusion downward from n-well 32b and the upward effect from n-type buried layer 24. For these reasons, the line defining the upper edge of region 28 is shown as a dashed line in FIG. 2b because in effect region 28 becomes doped with n-type dopants and, therefore, it represents the lower portion of n-type well 32b. In essence, therefore, n-type well 32b extends deeper from the upper surface of epitaxial layer 30 than does n-type well 32a. Finally, note that both n-type wells 32a and 32b are labeled with an N designation to further illustrate their n-type dopant concentration, and because n-type well 32b extends within region 28 then region 28 also is labeled with an N designation.

FIG. 2b also illustrates the formation of a p-type well 34, which may be formed either before or after the formation of n-type wells 32a and 32b. P-type well 34 is also formed by masking the upper surface of epitaxial layer 30 with an appropriate mask and implanting p- type dopants (e.g., boron) through the mask. For further sake of illustration, p-type well 34 is labeled with a P designation to illustrate its p-type dopant concentration.

FIG. 2c illustrates a cross-sectional view of transistor 20 after additional fabrication steps following those illustrated in FIG. 2b. A number of insulating regions 36 are formed, and they may be constructed using various techniques such as by forming field oxide regions or shallow trench isolation regions. Next, two mask and implanting steps take place such that P and N type diffusion regions, in either order, are formed self-aligned to insulating regions 36. Looking first to the p-type regions, they include regions 38 and 40. P-type region 38 is formed in p-type well 34 while p-type region 40 is formed in n-type well 32a. Further, p-type regions 38 and 40 are formed using a relatively high p-type dopant concentration and, thus, each is labeled with a P+ designation. Looking second to the n-type regions, they include regions 42 and 44. N-type region 42 is formed in n-type well 32b while n-type region 44 is formed in n-type well 32a. Further, n-type regions 42 and 44 are formed using a relatively high n-type dopant concentration and, thus, each is labeled with an N+ designation. Lastly, while not shown, one skilled in the art will appreciate that substrate 22 supports other devices and, indeed, many of these other devices will include the formation of regions using comparable doping concentrations and energy levels as that used for regions 38, 40, 42, and 44. For example, such other devices may include metal on semiconductor (MOS) transistors, and at the same the source/drain regions of these other devices are formed the same implants steps are preferably used to form regions 38, 40, 42, and 44. As a result, no additional steps beyond those already required for the other devices are needed to form regions 38, 40, 42, and 44.

Given the various locations and conductivity types of the regions of transistor 20 as well as the relative location of those regions with respect to substrate 22, one skilled in the art will readily appreciate that a PNP conductivity path may be established from p-type region 38 (along with p-type well 34 and p-type buried layer 26), to n-type well 32a (and n-type region 44), to p-type region 40. This conductivity path establishes a PNF transistor configuration and, for this reason, p-type region 38 provides the device collector and is indicated schematically as C₂, n-type well 32a and n-type region 44 provide the device base and n-type region 44 is indicated schematically as B₂, and p-type region 40 provides the device emitter and is indicated schematically as L₂. Moreover, having demonstrated the PNP conductivity path, one skilled in the art should also appreciate the complexity in properly forming p-type buried layer 26. Specifically, that layer must be sufficiently formed so that it properly prevents a punch through from occurring between the n-type regions above and below p-type buried layer 26, that is, between n-type well 32a and n-type buried layer 24. Higher concentration in p-type buried layer 26 also helps to suppress the vertical SCR (i.e., PNPN structure) from turning on. At the same time, however, if p-type buried layer 26 is too highly doped, then there is a risk of leakage between it and n-type buried layer 24 and degradation of PNP breakdown characteristics. Thus, the preferred embodiment dopant concentration and energy levels given above, as well as the formation of epitaxial layer 30 after forming p-type buried layer 26 in a previously-formed layer, are directed toward these concerns.

In addition to the connections and schematic indications of FIG. 2c discussed above, the preferred embodiment includes additional isolating structures as further shown in FIG. 2c and as appreciated also in view of FIG. 2d. Specifically, FIG. 2d illustrates a top view of transistor 20 where the various regions are shown to be generally circular by way of example to illustrate the isolation aspects of the preferred embodiment but not necessarily as an actual illustration of the geometry in which transistor 20 may be formed. From the perspective of FIG. 2d, one skilled in the art will appreciate that collector C₂ of transistor 20 is fully enveloped within an n-type isolation structure that is formed by n-type well 32b around the sides of collector C₂ (shown vertically in FIG. 2c) and by n-type buried layer 24 along its bottom (shown horizontally in FIG. 2c). In other words, in effect, a bowl-shaped structure is formed of n-type material to isolate the regions that fit within the interior of this bowl, where those regions, from outside moving inward, are the p-type well 34 and the p-type buried layer 26, as well as the n-type well 32a. This bowl-shaped isolation structure is electrically accessible by n-type region 42, which therefore is labeled schematically as isolation terminals IS₁. This same isolation aspect also may be appreciated in FIG. 2c. More particularly, in FIG. 2c, collector C₂ of transistor 20 is shown to include a p-type well 34 which has a side dimension 34s, and as shown in FIG. 2d side dimension 34s defines a continuous outside perimeter. Further, along the bottom 34b of p-type well 34 is p-type buried layer 26 which has a bottom 26b which defines the bottom of collector C₂ of transistor 20. Having defined the outside boundaries of collector C₂ of transistor 20, each of these boundaries is enclosed by an adjacent portion of the n-type isolation structure. Particularly, the n-type isolation structure includes n-type well 32b adjacent and outside of side dimension 34s of collector C₂ of transistor 20 and it includes n-type buried layer 24 adjacent and below bottom 26b of collector C₂ of transistor 20. Lastly, note that FIGS. 2c and 2d illustrate two terminals for collector C₂ and isolation terminal IS₁. However, because, as shown in FIG. 2d, p-type well 34 and n-type well 32b are both continuous (e.g., circular) regions, then alternatively only one terminal could be used for collector C₂ to bias p-type well 34 (and p-type buried layer 26) and only one terminal could be used for isolation terminal IS₁ to bias n-type well 32b (and n-type buried layer 24).

In the preferred embodiment for transistor 20, the isolation structure which includes n-type well 32b and n-type buried layer 24 is biased at an electrical potential equal to the maximum collector voltage for transistor 20. Using this approach, note that if any holes would tend to stray from the semiconductor regions that form collector C₂ (i.e., p-type region 38, p-type well 34, and p-type buried layer 26), then these holes are effectively repelled by the retarded electrical field established in the PN junction by the relatively high potential imposed on the isolation structure and, therefore, are more likely to be maintained with the regions forming collector C₂. Thus, the isolation structure provides the ability to maintain these stray holes within the enclosed p-type regions and thereby prevent such holes from reaching substrate 22. In addition, note that by keeping the isolation structure at a relatively high potential, there is little or no chance that the PN junction between the p-type regions forming collector C₂ and the n-type regions forming the isolation structure will become forward biased. Lastly, note that one skilled in the art may construct various different known circuits to achieve the electrical biasing described immediately above.

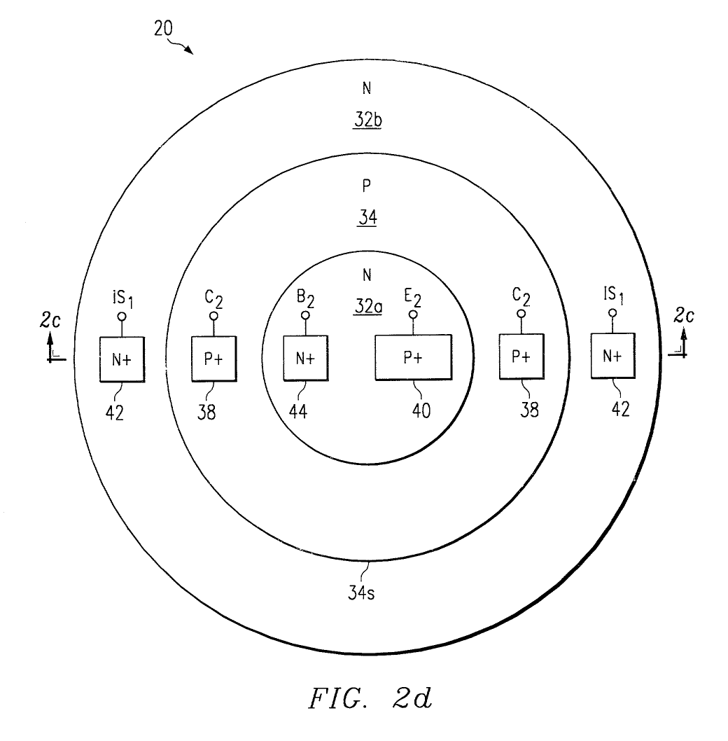

FIG. 3 illustrates a cross-sectional view of a preferred embodiment electrical hole isolator circuit 50. Circuit 50 includes many of the same regions and structures of transistor 20 discussed above, and to illustrate the comparable features the same reference numbers for those features are carried forward from the previous Figures to FIG. 3. Moreover, the same above-described fabrication steps are preferably used to create the features in circuit 50. Circuit 50 differs from transistor 20 in the identification of some of the nodes to which an external voltage may be applied and by the illustration of a dashed box which as detailed below is intended to represent any of various types of circuits that may be referred to as a hole injector 52.

Looking to the differences presented in circuit 50 in greater detail, two hole guard terminals HG₁ are provided through which a potential may be connected, via p-type region 38, to p-type well 34 (and p-type buried layer 26), and two isolation terminals IS₂ are provided through which a potential may be connected, via n-type region 42, to n-type well 32b (and n-type buried layer 24). Alternatively, only one of hole guard terminals HG₁ and one of isolation terminals IS₁ could be included to provide an electrical bias to regions 38 and 42, respectively. Hole injector 52 may be any type of circuit that, during operation, may be prone to release stray holes that, without additional protection, could reach substrate 22. As examples, rather than the base and emitter of a transistor as shown with respect to transistor 20 described above, hole injector 52 could be any of: (1) an output power device which gets forward biased when switching inductive loads; (2) a p-channel MOS transistor which can have forward biased its drain or source during the operation; (3) a power device operating at high current level, which tends to generate more holes; (4) any nodes connected to an input/output pin; (5) a power devices driving an inductive load in that during the switching of the states, the node will inject holes; and (6) any nodes connected to noisy digital power supply. In any event, therefore, circuit 50 is intended to illustrate that circuit types other than the above-described PNP transistor could be formed within n-type well 32a and still benefit from the structure illustrated in FIG. 3 as well as in earlier Figures.

In view of the above, the hole guard terminals HG₁ connect to p-type regions 38, 34, and 26, thereby creating a p-type hole guard structure, while the isolation terminals IS₂ connect to n-type regions 42, 32b, and 24, thereby creating an n-type hole isolation structure. The p-type hole guard structure fully encloses n-type well 32a along its sides 32 as using p-type well 34 and along its bottom 32ab using p-type buried layer 26. The n-type isolation structure fully encloses the p-type hole guard structure along its sides 34s using n-type well 32b and along its bottom 26b using n-type buried layer 24. Lastly, in the preferred embodiment, the p-type hole guard structure and the n-type isolation structure may be biased at electrical potentials according to two different approaches, each of which is described below.

In a first approach to biasing the p-type hole guard structure and the n-type isolation structure, isolation terminal IS₂ is connected to hole guard HG₁, and the two connected terminals are connected to the lowest anticipated operating potential for hole injector 52 (e.g., ground). Using this approach, note that if any holes stray from n-type well 32a, then they should be collected in the p-type hole guard structure (i.e., p-type well 34 and p-type buried layer 26). In other words, hole guard structure, like the regions forming the collector in transistor 20, operates to collect the stray holes. Moreover, by connecting the same potential to the p-type hole guard structure and the n-type isolation structure surrounding it, then there is little chance that the PN junction between the two can become active and, hence, the holes should not stray outside of the p-type hole guard structure toward substrate 22. However, should those holes stray farther, then those holes are attracted to the relatively low circuit potential which is connected via isolation terminal IS₂ to the n-type isolation structure (i.e., n-type well 32b and n-type buried layer 24).

In a second approach to biasing the p-type hole guard structure and the n-type isolation structure, hole guard terminal HG₁ is connected to the lowest anticipated operating potential for hole injector 52 while isolation terminal IS₂ is connected to the highest anticipated operating potential for hole injector 52 (e.g., V_{DD}). Under this approach, the PN junction between the p-type hole guard and the n-type isolation structure is reverse biased, thereby preventing holes from crossing that junction. However, should any holes tend toward straying beyond the boundary of the p-type hole guard then they are repelled by the relatively high potential in the n-type isolation structure. This latter approach must be evaluated in terms of the possible result occurring because of the NPN interfaces between n-type well 32a, p-type hole guard structure, and the n-type isolation structure. In other words, due to these interfaces, there should be consideration taken so that the NPN interface is not enabled, that is, it is instead desirable that the interfaces remain latent. However, this goal may not be possible depending on the charge imposed on n-type well 32a. Thus, one skilled in the art should consider the tradeoffs of the two above-described preferred embodiment approaches for a given circuit implementation. In addition, one skilled in the art also may construct various different known circuits to achieve the alternative electrical biasing described immediately above.

From the above, it may be appreciated that the above embodiments provide an electronic circuit with an electrical hole isolator, where the isolator may be combined beneficially with a vertical PNP transistor. Such a device provides various benefits, including the ability to isolate a semiconductor substrate from holes that might otherwise stray into the substrate and undesirably affect the operation of other devices sharing that substrate. In addition, the preferred embodiments may be implemented as various alternatives as shown above. Further, still additional alternatives are contemplated. For example, the conductivity types shown above may be reversed to thereby create a vertical NPN device, although the use of an n-type substrate may be less desirable or not feasible in certain circumstances. As another example, while the dopant implant concentrations and energy levels given above are preferred, these may be varied based on various circuit considerations. Still other examples will be ascertainable by one skilled in the art. Consequently, while the present embodiments have been described in detail, various substitutions, modifications or alterations could be made to the descriptions set forth above without departing from the inventive scope which is defined by the following claims.

1. An electronic circuit, comprising:
a semiconductor substrate;
a first layer in a fixed physical relation to the semiconductor substrate;
a well formed in the first layer, wherein the well comprises a first conductivity type and has a side dimension and a bottom dimension;
a first enclosure surrounding the side dimension and the bottom dimension of the well, wherein the first enclosure comprises a second conductivity type complementary of the first conductivity type and has a side dimension and a bottom dimension; and
a second enclosure surrounding the side dimension and the bottom dimension of the first enclosure, wherein the second enclosure comprises the first conductivity type.

2. The electronic circuit of claim 1:
wherein the well comprises a first well; and
wherein the first enclosure comprises:
a second well surrounding the side dimension of the first well; and
a buried layer adjacent the bottom dimension of the first well.

3. The electronic circuit of claim 2 wherein the first conductivity type comprises n-type and wherein the second conductivity type comprises p-type.

4. The electronic circuit of claim 2:
wherein the buried layer comprises a first buried layer; and
wherein the second enclosure comprises:
a third well surrounding a side dimension of the second well; and
a second buried layer adjacent a bottom dimension of the first buried layer.

5. The electronic circuit of claim 4:
wherein the first layer comprises an epitaxial layer; and
wherein the first and second buried layers are formed in the substrate.

6. The electronic circuit of claim 5:
wherein the second and third wells are formed in the epitaxial layer.

7. The electronic circuit of claim 6 wherein the first conductivity type comprises n-type and wherein the second conductivity type comprises p-type.

8. The electronic circuit of claim 6:
wherein the first well comprises circuitry operable to emit electrical holes in response to an operating voltage that may swing between a predetermined low voltage and a predetermined high voltage;
and further comprising:
a first terminal for applying a voltage potential to the first enclosure; and
a second terminal for applying a voltage potential to the second enclosure.

9. The electronic circuit of claim 8 and further comprising circuitry for connecting the first terminal to the second terminal.

10. The electronic circuit of claim 9 wherein the first conductivity type comprises n-type and wherein the second conductivity type comprises p-type.

11. The electronic circuit of claim 10 and further comprising circuitry for connecting the first terminal and the second terminal to the predetermined low voltage.

12. The electronic circuit of claim 10 and further comprising:
circuitry for connecting the first terminal to the predetermined low voltage; and
circuitry for connecting the second terminal to the predetermined high voltage.

13. The electronic circuit of claim 6:
wherein the first enclosure comprises a transistor collector;
wherein the first well comprises a transistor base;
and further comprising a transistor emitter formed as a region within the first well.

14. The electronic circuit of claim 13 wherein the transistor comprises a vertical PNP transistor.

15. The electronic circuit of claim 14:
wherein the transistor collector is operable in response to an operating voltage that may swing between a predetermined low voltage and a predetermined high voltage;
and further comprising a terminal for applying a voltage potential to the second enclosure.

16. The electronic circuit of claim 15 and further comprising circuitry for connecting the terminal to the predetermined high voltage.

17. The electronic circuit of claim 4:
wherein the first well comprises circuitry operable to emit electrical holes in response to an operating voltage that may swing between a predetermined low voltage and a predetermined high voltage;
and further comprising:
a first terminal for applying a voltage potential to the first enclosure; and
a second terminal for applying a voltage potential to the second enclosure.

18. The electronic circuit of claim 17 and further comprising circuitry for connecting the first terminal to the second terminal.

19. The electronic circuit of claim 18:
wherein the first conductivity type comprises n-type and wherein the second conductivity type comprises p-type;
and further comprising circuitry for connecting the first terminal and the second terminal to the predetermined low voltage.

20. The electronic circuit of claim 18:
wherein the first conductivity type comprises n-type and wherein the second conductivity type comprises p-type;
and further comprising:
circuitry for connecting the first terminal to the predetermined low voltage; and
circuitry for connecting the second terminal to the predetermined high voltage.

21. The electronic circuit of claim 4:
wherein the first enclosure comprises a transistor collector;
wherein the first well comprises a transistor base;
and further comprising a transistor emitter formed as a region within the first well.

22. A method of forming an electronic circuit, comprising the steps of:
forming a first layer in a fixed physical relation to a semiconductor substrate;
forming a well formed in the first layer, wherein the well comprises a first conductivity type and has a side dimension and a bottom dimension;
forming a first enclosure surrounding the side dimension and the bottom dimension of the well, wherein the first enclosure comprises a second conductivity type complementary of the first conductivity type and has a side dimension and a bottom dimension; and
forming a second enclosure surrounding the side dimension and the bottom dimension of the first enclosure, wherein the second enclosure comprises the first conductivity type.

23. The method of claim 22:
wherein the well comprises a first well; and
wherein the step of forming first enclosure comprises the steps of:
forming a second well surrounding the side dimension of the first well; and
forming a buried layer adjacent the bottom dimension of the first well.

24. The method of claim 23 wherein the step of forming a buried layer occurs prior to the step of forming the well.

25. The method of claim 23 wherein the first conductivity type comprises n-type and wherein the second conductivity type comprises p-type.

26. The method of claim 25 wherein the step of forming a buried layer comprises implanted at a dosage on the order of 5e¹⁵/cm² and at an energy on the order of 60 keV.

27. The method of claim 25:
wherein the buried layer comprises a first buried layer; and
wherein the step of forming a second enclosure comprises the steps of:
forming a third well surrounding a side dimension of the second well; and
forming a second buried layer adjacent a bottom dimension of the first buried layer.

28. The method of claim 27 wherein the step of forming a second buried layer comprises implanted at a dosage on the order of 8e¹³/cm² and at an energy on the order of 60 keV.

29. The method of claim 27 wherein the step of forming a second buried layer occurs prior to the step of forming the third well and prior to the step of forming the second well.

30. The method of claim 22:
wherein the first enclosure comprises a transistor collector;
wherein the first well comprises a transistor base;
and further comprising the step of forming a transistor emitter as a region within the well.
